(19) United States
(12) Patent Application Publication
(10) Pub. No.: US 2026/0342293 A1
(43) Pub. Date: Oct. 29, 2026

(54) MODULATOR, MODULATION METHOD AND CLASS D AMPLIFIER

(71) Applicant: Nanjing Silergy Micro Technology Co., Ltd., Nanjing (CN)

(72) Inventor: Bin Zhang, Nanjing (CN)

(21) Appl. No.: 19/650,587

(22) Filed: Apr. 17, 2026

(30) Foreign Application Priority Data
Apr. 27, 2025 (CN) 202510543900.9

(51) Int. Cl. H03F 3/217; H03K 3/017; H03K 5/00; H03K 5/01

(52) U.S. Cl. CPC H03F 3/217; H03K 3/017; H03F 2200/03; H03F 2200/351; H03K 2005/00013; H03K 5/01

(57) ABSTRACT

A modulator, configured to convert an input signal into a pulse-width modulation signal, can include: an envelope detection unit, configured to receive the input signal, to detect an envelope of the input signal, and to output an amplitude of the envelope of the input signal; where the modulator is configured to reduce a duty cycle of an initial signal according to the amplitude of the envelope, in order to output the pulse-width modulation signal; and where the initial signal is obtained by performing pulse-width modulation on the input signal.

### RELATED APPLICATIONS

This application claims the benefit of Chinese Patent Application No. 202510543900.9, filed on Apr. 27, 2025, which is incorporated herein by reference in its entirety.

### FIELD OF THE INVENTION

The present invention generally relates to the field of power supply packaging technology, and more particularly to modulators, modulation methods, and Class D amplifiers.

### BACKGROUND

In existing bridge differential modulation (BD modulation), the duty cycle of the high-frequency pulse signal obtained for small signals can be close to 50%. A large duty cycle can lead to large ripple currents in a subsequent low-pass filtering process, which can result in conduction and switching losses that may not be reduced, as well as high power consumption.

### BRIEF DESCRIPTION OF THE DRAWINGS

FIG. 1 is a schematic block diagram of an example Class D amplifier, in accordance with embodiments of the present invention.

FIG. 2 is a waveform diagram of an example reduction of a duty cycle of a pulse-width modulation signal based on a delay parameter according to a delay parameter, in accordance with embodiments of the present invention.

FIG. 3 is a schematic block diagram of a first example modulator, in accordance with embodiments of the present invention.

FIG. 4 is a waveform diagram of an example relationship between an amplitude of the envelope and a delay, in accordance with embodiments of the present invention.

FIG. 5 is a waveform diagram of an example variation of a delay parameter with an amplitude of the envelope, in accordance with embodiments of the present invention.

FIG. 6 is a schematic block diagram of a second example modulator, in accordance with embodiments of the present invention.

FIG. 7 is a schematic block diagram of an example delay unit, in accordance with embodiments of the present invention.

FIG. 8 is a waveform diagram of example operation of the modulator, in accordance with embodiments of the present invention.

FIG. 9 is a flow diagram of an example modulation method, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

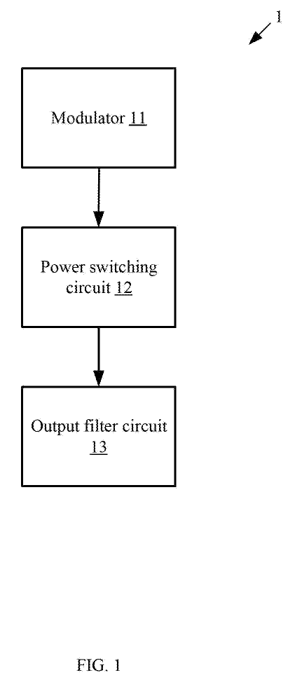

Referring now to FIG. 1, shown is a schematic block diagram of an example Class D amplifier, in accordance with embodiments of the present invention. In this particular example, the Class D amplifier 1 can include modulator 11, power switching circuit 12, and output filter circuit 13. Modulator 11 can convert an input signal (e.g., an audio signal) into a pulse-width modulation signal. This particular example can be applicable to both Class D amplifiers that process a single-ended signal as the audio signal, and those that use a differential signal as the audio signal.

In particular embodiments, during the process of converting the input signal into the pulse-width modulation signal to be amplified, modulator 11 can detect an envelope of the input signal, determine a delay parameter according to the amplitude of the envelope, and reduce the duty cycle of an initial signal according to the delay parameter, in order to output a corresponding pulse-width modulation signal to be amplified. The delay parameter can dynamically change in real time according to the amplitude of the envelope. The initial signal can be a signal obtained by performing pulse-width modulation on the input signal. The duty cycle of the output pulse-width modulation signal can be dynamically reduced relative to the initial signal according to the magnitude of the delay parameter.

Power switching circuit 12 can amplify the pulse-width modulation signal and output an amplified pulse-width modulation signal. Power switching circuit 12 can be the execution part of the Class D amplifier, controlling rapid turn-on and turn-off of power switching devices (e.g., MOSFETs, GaN, etc.), thereby converting the modulated initial signal into a high-power pulse-width modulation signal (e.g., the amplified initial signal). Since the power switching devices operate in saturation or cutoff states rather than the linear amplification region, energy loss can be extremely low, and the efficiency of the Class D amplifier can be much higher than traditional Class A, B, or AB amplifiers. Output filter circuit 13 can filter the amplified pulse-width modulation signal and then drive a load. In one embodiment, the output filter circuit 13 can include an LC filter circuit, forming a low-pass filter to filter the received signal and reconstruct the audio signal.

In some conventional approaches, when there is no audio signal or the amplitude of the audio signal is low, the duty cycle of the initial signal can be high, e.g., close to 50%. The high duty cycle leads to large ripple currents in the filter circuit, resulting in high conduction loss and switching loss in conventional Class D amplifiers. In particular embodiments, modulator 11 may determine a delay parameter according to the amplitude of the envelope and reduce the duty cycle of the initial signal according to the delay parameter, in order to output the corresponding pulse-width modulation signal. When the amplitude of the envelope is large, the delay parameter determined can be small, thereby not adjusting the duty cycle by a large margin or not adjusting the duty cycle. When no audio signal is input or the amplitude of the envelope of the audio signal is small, the delay parameter determined can be large, in order to reduce the duty cycle of the initial signal by a large margin and keep the duty cycle of the pulse-width modulation signal relatively small in the small-signal state, thereby reducing ripple current and lowering power loss.

In the description herein, the delay parameter may refer to a value corresponding to the delay time applied to the initial signal, and the delay parameter can be the delay time itself, or a count value, voltage value, or current parameter value, which can represent the delay time. One exemplary way to reduce the duty cycle using different delay parameters is to delay the initial signal according to the delay parameter, and then perform a logic AND operation on the initial signal before delay and the delayed signal after delay, thereby obtaining a pulse-width modulation signal with a reduced duty cycle.

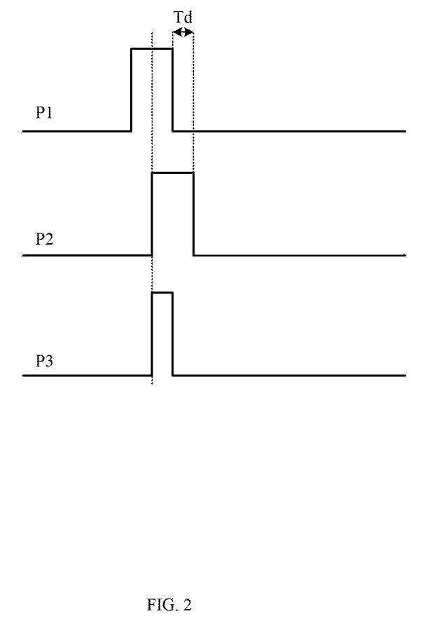

Referring now to FIG. 2, shown is a waveform diagram of an example reduction of a duty cycle of a pulse-width modulation signal based on a delay parameter according to a delay parameter, in accordance with embodiments of the present invention. In this particular example, initial signal P1 can be delayed according to delay parameter Td to obtain delayed signal P2. Then, a logic AND operation can be performed on initial signal P1 and delayed signal P2, in order to generate pulse-width modulation signal P3. Since pulse-width modulation signal P3 only retains the overlapping portion of initial signal P1 and delayed signal P2, the duty cycle can be reduced. The part where the duty cycle is reduced can correspond to delay parameter Td.

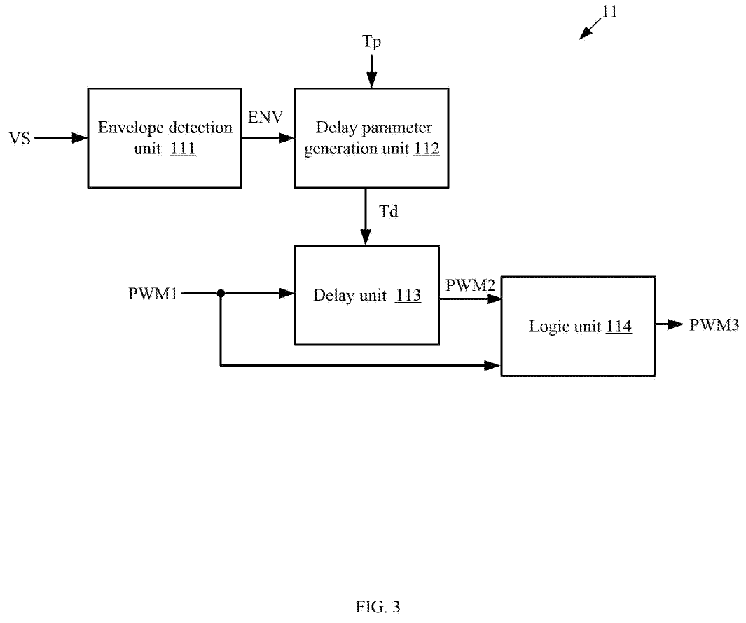

Referring now to FIG. 3, shown is a schematic block diagram of a first example modulator, in accordance with embodiments of the present invention. In this particular example, modulator 11 can include envelope detection unit 111, delay parameter generation unit 112, delay unit 113, and logic unit 114. Envelope detection unit 111 can receive audio signal VS (e.g., the input signal), detect the envelope of audio signal VS, and output amplitude ENV of the envelope of the audio signal. Delay parameter generation unit 112 can generate delay parameter Td according to the amplitude ENV of the envelope. Delay unit 113 can output delayed signal PWM2 delayed relative to initial signal PWM1 according to delay parameter Td. Logic unit 114 can reduce the duty cycle of initial signal PWM1 according to delayed signal PWM2 and may output pulse-width modulation signal PWM3.

In one embodiment, different amplitudes of the envelope can determine different delay parameters according to a predetermined relationship between the amplitude of the envelope and a delay (also referred to as a static control curve). In one example, the static control curve can be a piecewise function. When the amplitude of the envelope is small, the delay parameter can be a fixed larger value (a first value). As the amplitude of the envelope increases beyond a predetermined envelope threshold, the delay parameter may transition to a second value that varies linearly with amplitude ENV of the envelope. For example, the delay parameter can continuously decrease to zero as the amplitude of the envelope further increases. In another example, when the amplitude of the envelope is less than a preset value, the delay parameter can be a fixed value, and when the amplitude of the envelope is greater than the preset value, the delay parameter can be zero.

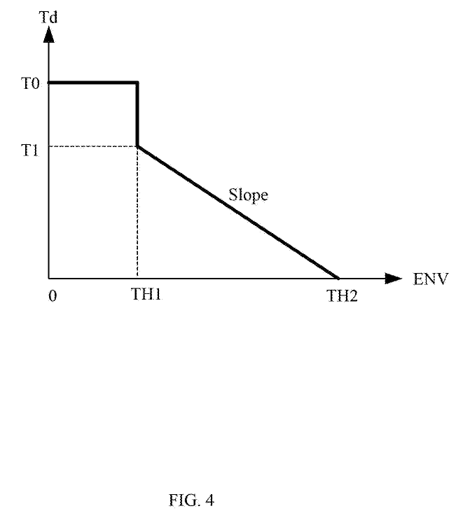

Referring now to FIG. 4, shown is a waveform diagram of an example relationship between an amplitude of the envelope and a delay, in accordance with embodiments of the present invention. In this particular example, the relationship between an amplitude of the envelope and a delay can be a piecewise function. The parameters of this piecewise function can include envelope threshold TH1, envelope threshold TH2, and slope ‘Slope’. The horizontal axis of the graph in FIG. 4 can be amplitude ENV of the envelope, and the vertical axis can be delay parameter Td. When the amplitude of the envelope is small, between 0 and envelope threshold TH1, delay parameter Td can be fixed value T0. When the amplitude of the envelope is between envelope thresholds TH1 and TH2, delay parameter Td can be a linear function that gradually decreases as the amplitude of the envelope increases with a decreasing slope ‘Slope’.

At envelope threshold TH1, delay parameter Td can transition to a predetermined value T1, where T1<T0. Until the amplitude of the envelope is greater than threshold TH2, delay parameter Td may drop to zero. The relationship between an amplitude of the envelope and a delay can be predetermined by parameters of the Class D amplifier. Here, fixed value T0 can be related to the power consumption and audio performance of the Class D amplifier. When fixed value T0 is larger, the power consumption of the Class D amplifier for small signals can be lower, and efficiency can be higher. When the amplitude of the envelope is between thresholds TH1 and TH2, the slope ‘Slope’ can be related to the power consumption of the Class D amplifier. The larger the slope, the lower the power consumption of the Class D amplifier.

Further, at least one time parameter T_{P} for controlling delay variation can also be input to delay parameter generation unit 112 to make the delay parameter change more smoothly when it changes according to the amplitude of the envelope, in order to avoid the impact of audio changes on sound quality. For example, time parameter T_{P} for controlling delay variation may include at least one of a hold time, a release time, and a startup time. When the amplitude of the envelope decreases causing the delay parameter to need to change according to the relationship between the amplitude of the envelope and a delay, the delay parameter may remain unchanged for the hold time and then changes at a speed defined by the release time. When the amplitude of the envelope increases causing the delay parameter to need to change according to the relationship between the amplitude of the envelope and a delay, the delay parameter can change at a speed defined by the startup time. Typically, the startup time can be less than the hold time, such that the delay parameter may drop to the delay parameter corresponding to a higher amplitude of the envelope in a shorter time. This can allow the delay parameter to change smoothly, thus avoiding noise in the audio signal.

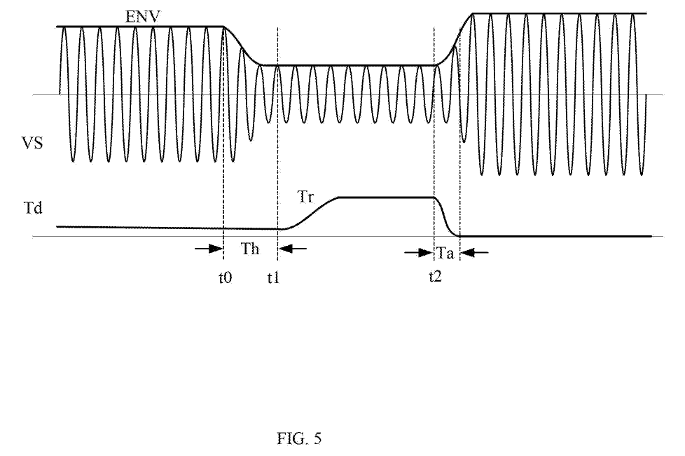

Referring now to FIG. 5, shown is a waveform diagram of an example variation of a delay parameter with an amplitude of the envelope, in accordance with embodiments of the present invention. In this particular example, before time t0, the amplitude of the envelope of audio signal VS may remain at a high point, and delay parameter Td may remain at a small value. After time t0, the amplitude of the envelope of audio signal VS can decrease, thus causing delay parameter Td to need to increase according to the relationship between the amplitude of the envelope and a delay shown in FIG. 4. At this point, actual delay parameter Td may not change immediately, but may remain unchanged for a period defined by hold time Th. Then, at time t1,that is, time (t0+Th), the delay parameter can be changed to a value corresponding to the current amplitude of the envelope at a speed defined by release time Tr. That is, the change process can be completed within duration Tr corresponding to the release time. Since the change process can be smoothed by hold time Th and release time Tr, this can prevent noise caused by excessively rapid changes.

After time t2, the amplitude of the envelope of audio signal VS can increase, thus causing delay parameter Td to need to decrease according to the relationship between the amplitude of the envelope and a delay shown in FIG. 4. Delay parameter Td can be changed to the corresponding target value at a speed defined by startup time Ta; that is, the change process can be completed within duration Ta corresponding to the startup time). This process can be shorter than the change time during the rising phase of delay parameter Td; that is, the startup time can be less than the hold time, such that the delay parameter can be dropped to the delay parameter corresponding to a higher amplitude of the envelope in a shorter time to avoid noise.

Referring back to FIG. 3, delay unit 113 can delay initial signal PWM1 according to delay parameter Td and output delayed signal PWM2. As mentioned above, initial signal PWM0 can be a pulse-width modulation signal obtained by comparing the audio signal against a triangular wave carrier having a frequency higher than the audio signal. For example, a comparator may receive the audio signal and a triangular wave signal, and when the audio signal is higher than the triangular wave signal, the comparator may output a high level. Also, when the audio signal is lower than the triangular wave signal, the comparator may output a low level, thereby obtaining initial signal PWM1.

In another optional example, delay unit 113 can delay the carrier according to the delay parameter, and may perform pulse-width modulation on the input signal according to the delayed carrier to output the delayed signal. Here, the carrier can be used for performing pulse-width modulation on the input signal to determine the initial signal. Logic unit 114 can reduce the duty cycle of initial signal PWM1 according to delayed signal PWM2 and output pulse-width modulation signal PWM3. In one embodiment, logic unit 114 can be an AND gate that may receive initial signal PWM1 and delayed signal PWM2 and can perform a logic AND operation to output pulse-width modulation signal PWM3 with a reduced duty cycle. The reduction amount of the duty cycle can be directly related to the delay parameter. When the delay parameter is large, the reduction of the duty cycle can be large. When the delay parameter is small, the reduction of the duty cycle can be small. When the delay parameter is 0 (e.g., delayed signal PWM2 has the same duty cycle as initial signal PWM1), the duty cycle may remain unchanged after output.

In the embodiment shown in FIG. 3, delay unit 113 and logic unit 114 can be single-channel processing circuits, thus applicable to application scenarios where the input signal is a single-ended signal. Delay unit 113 and logic unit 114 can also be dual-channel parallel processing circuits, capable of processing the in-phase and anti-phase signals of a differential signal in parallel.

In audio signal processing, differential signals are one of the common forms of audio signals. A differential signal can include an in-phase signal and an anti-phase signal. The in-phase and anti-phase signals are a pair of signals with opposite phases. Using differential signals as audio signals can reduce external electromagnetic interference and noise. Since differential signals are widely used currently, the following description takes a modulator processing differential signals as an example for further explanation.

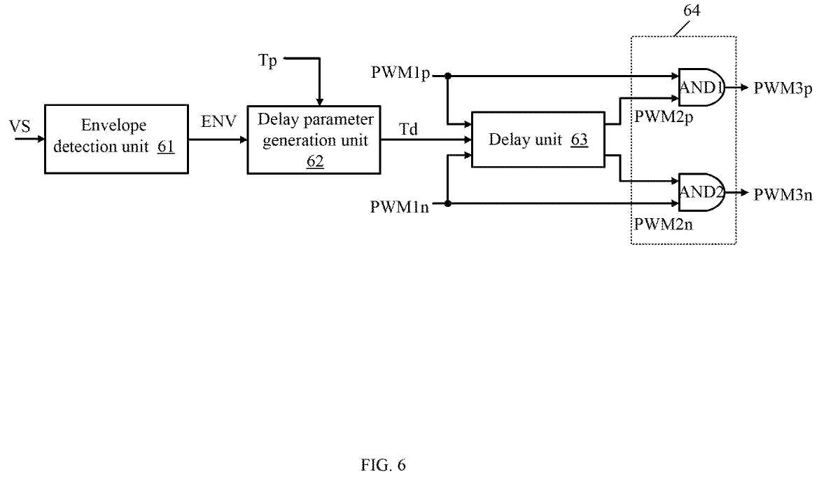

Referring now to FIG. 6, shown is a schematic block diagram of a second example modulator, in accordance with embodiments of the present invention. In this particular example, the modulator can include envelope detection unit 61, delay parameter generation unit 62, delay unit 63, and logic unit 64. Envelope detection unit 61 can receive audio signal VS and output amplitude ENV of an envelope of the audio signal. Delay parameter generation unit 62 can generate delay parameter Td according to amplitude ENV of the envelope. Further, delay parameter generation unit 62 can receive at least one time parameter Tp for controlling delay variation to make delay parameter Td change more smoothly when it changes according to the amplitude of the envelope, such that the impact of excessively rapid changes on sound quality, prevent noise, and reduce harmonics can be substantially avoided. For example, time parameter Tp for controlling delay variation may include at least one of a hold time, a release time, and a startup time.

In particular embodiments, audio signal VS can be a differential signal, including in-phase signal VSp and anti-phase signal VSn. The initial signals obtained by triangular wave modulation of the audio differential signal can include in-phase initial signal PWM1p and anti-phase initial signal PWM1n, corresponding to in-phase signal VSp and anti-phase signal VSn of the audio signal respectively. The envelope detection can be performed on the single-ended signal before conversion to a differential signal or simultaneously receive both the in-phase and anti-phase signals, or only one of the in-phase and anti-phase signals. The relationship between the amplitude of the envelope and a delay can differ when performing envelope detection on a single-ended signal versus a differential signal. However, it may be necessary to obtain the corresponding in-phase initial signal PWM1p and anti-phase initial signal PWM1n based on in-phase signal VSp and anti-phase signal VSn, respectively.

Delay unit 63 can delay in-phase initial signal PWM1p and anti-phase initial signal PWM1n according to delay parameter Td determined by amplitude ENV of the envelope of the audio signal and at least one time parameter Tp, and may output in-phase delayed signal PWM2p being delayed and anti-phase delayed signal PWM2n being delayed. In the example of FIG. 6, delay unit 63 can receive in-phase initial signal PWM1p, anti-phase initial signal PWM1n, and delay parameter Td, and may separately delay in-phase initial signal PWM1p, anti-phase initial signal PWM1n in two channels, in order to generate the corresponding in-phase delayed signal PWM2p delayed relative to the in-phase initial signal, and anti-phase delayed signal PWM2n delayed relative to the anti-phase initial signal.

Logic unit 64 can include AND gates AND1 and AND2. AND gate AND1 can receive in-phase initial signal PWM1p and in-phase delayed signal PWM2p, may perform a logic AND operation on in-phase initial signal PWM1p and in-phase delayed signal PWM2p, and can output in-phase pulse-width modulation signal PWM3p having duty cycle that is reduced according to delay parameter Td. AND gate AND2 can receive anti-phase initial signal PWM1n and anti-phase delayed signal PWM2n, may perform a logic AND operation on anti-phase initial signal PWM1n and anti-phase delayed signal PWM2n, and can output anti-phase pulse-width modulation signal PWM3n having a duty cycle that is reduced according to the delay parameter. Logic unit 64 may also include other necessary circuits, such as drivers and buffers.

In some conventional approaches, when the audio signal is a differential signal, no audio signal is supplied or the amplitude of the audio signal is low, the common-mode duty cycle of the two pulse-width modulation signals can be relatively high, close to 50%. In particular embodiments, due to the reduction in duty cycle, the common-mode components between the in-phase and anti-phase pulse-width modulation signals are reduced, which can further reduce losses caused by common-mode components. Moreover, when no audio signal is supplied or the amplitude of the audio signal is low, the duty cycle reduction can be maximized, thereby reducing power loss in the small-signal state. For example, delay unit 63 can be implemented in various ways, such as RC delay circuits, digital delay circuits, analog delay lines, etc., and other implementations can also be adopted, where the generation and delay of the initial signal are both integrated into the delay unit.

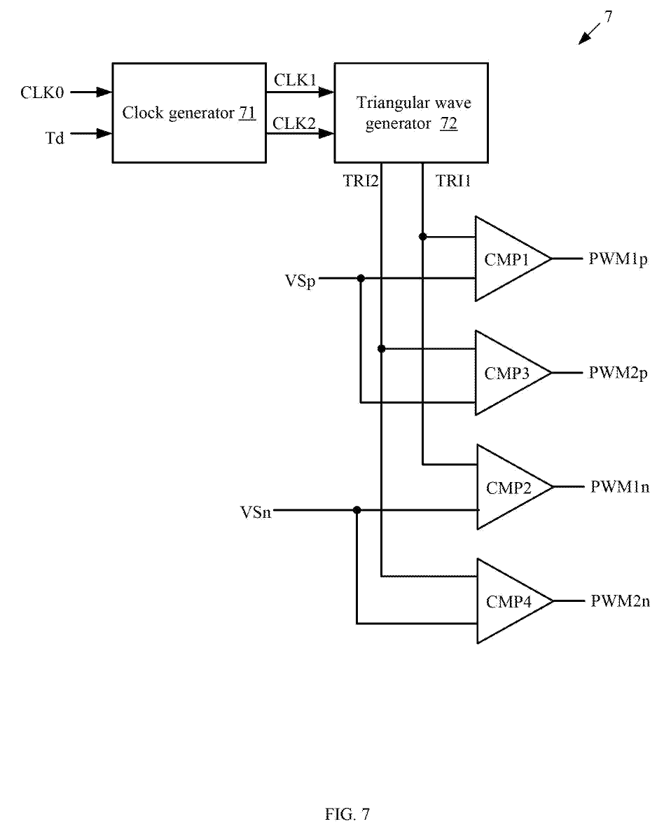

Referring now to FIG. 7, shown is a schematic block diagram of an example delay unit, in accordance with embodiments of the present invention. In this particular example, delay unit 7 can receive in-phase signal VSp and anti-phase signal VSn of the audio signal and delay parameter Td and simultaneously performs generation and delay operations for in-phase initial signal PWM1p and anti-phase initial signal PWM1n. Delay unit 7 can include clock generator 71, triangular wave generator 72, and comparison unit. Clock generator 71 may input a reference clock CLK0 and delay parameter Td and may generate clock signal CLK1 and clock signal CLK2 (e.g., that is delayed relative to clock signal CLK1 according to delay parameter Td), based on reference clock CLK0 and delay parameter Td.

Triangular wave generator 72 then may generate a corresponding triangular wave signals TRI1 and TRI2 according to clock signals CLK1 and CLK2, respectively. Triangular wave signals TRI1 and TRI2 have the same frequency, and triangular wave signal TRI2 can be delayed relative to triangular wave signal TRI1 by a time corresponding to delay parameter Td. The comparison unit can respectively compare in-phase signal VSp against triangular wave signals TRI1 and TRI2, in order to respectively generate in-phase initial signal PWM1p and in-phase delayed signal PWM2p delayed relative to the in-phase initial signal. The comparison unit can also respectively compare the anti-phase signal VSn against triangular wave signals TRI1 and TRI2, in order to respectively generate anti-phase initial signal PWM1n and anti-phase delayed signal PWM2n delayed relative to the anti-phase initial signal. For example, the comparison unit can include four comparators: CMP1, CMP2, CMP3, and CMP4.

Comparator CMP1 may receive in-phase signal VSp of the audio signal and triangular wave signal TRI1 and can output in-phase initial signal PWM1p. Comparator CMP2 may receive the anti-phase signal VSn of the audio signal and triangular wave signal TRI1 and can output anti-phase initial signal PWM1n. Comparator CMP3 may receive in-phase signal VSp of the audio signal and triangular wave signal TRI2. Since triangular wave signal TRI2 can be delayed relative to triangular wave signal TRI1 by delay parameter Td, and as carriers, the frequencies of triangular wave signals TRI1 and TRI2 can be much higher than that of the audio signal, and the change of the audio signal can be negligible. Therefore, the signal output by comparator CMP3 may be in-phase delayed signal PWM2p, which can be in-phase initial signal PWM1p delayed by delay parameter Td.

Similarly, comparator CMP4 may receive anti-phase signal VSn of the audio signal and triangular wave signal TRI2 and can output the delayed anti-phase delayed signal PWM2n. In this way, the differential initial signals and the delayed differential delayed signals can be obtained synchronously. For the delay unit of this implementation, on one hand, because the delay can be performed via clock signals, precision can be high. On the other hand, the initial signals and the delayed signals are generated through the same number of circuit stages, avoiding undesired delays introduced by differences in circuit stages, further improving signal accuracy.

After obtaining in-phase initial signal PWM1p, anti-phase initial signal PWM1n, in-phase delayed signal PWM2p, and anti-phase delayed signal PWM2n, logic AND operations can further be performed to output the duty-cycle-reduced pulse-width modulation signals PWM3p and PWM3n. For example, performing a logic AND operation on in-phase initial signal PWM1p and in-phase delayed signal PWM2p may yield in-phase pulse-width modulation signal PWM3p. Performing a logic AND operation on anti-phase initial signal PWM1n and anti-phase delayed signal PWM2n may yield anti-phase pulse-width modulation signal PWM3n.

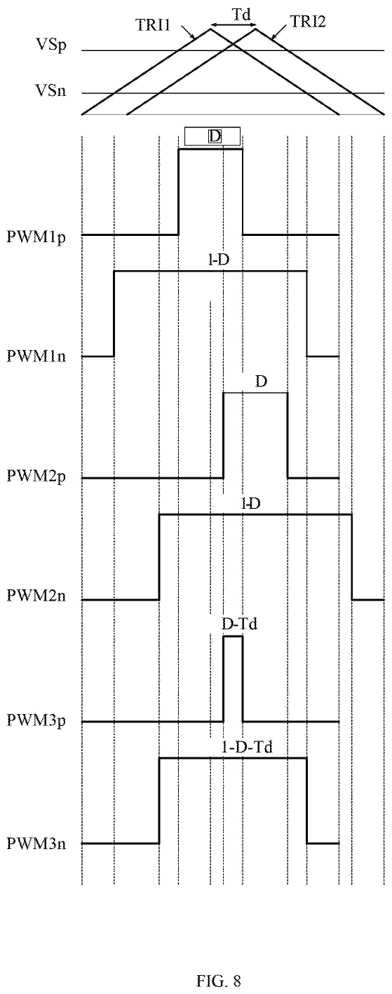

Referring now to FIG. 8, shown is a waveform diagram of example operation of the modulator, in accordance with embodiments of the present invention. In this particular example, the change of in-phase signal VSp and anti-phase signal VSn of the audio signal within one period relative to triangular wave signals TRI1 and TRI2 can be negligible. Therefore, in FIG. 8, in-phase signal VSp and anti-phase signal VSn appear as straight lines. Triangular wave signal TRI2 can be delayed relative to triangular wave signal TRI1 by a time corresponding to delay parameter Td. Through respective comparison operations, in-phase initial signal PWM1p, anti-phase initial signal PWM1n, in-phase delayed signal PWM2p, and anti-phase delayed signal PWM2n can be obtained by modulation.

In-phase initial signal PWM1p can be obtained by comparing in-phase signal VSp against triangular wave signal TRI1. In-phase delayed signal PWM2p can be obtained by comparing in-phase signal VSp against triangular wave signal TRI2. The duty cycle of in-phase delayed signal PWM2p can be the same as that of in-phase initial signal PWM1p, and in-phase delayed signal PWM2p can be delayed by time Td relative to in-phase initial signal PWM1p. Anti-phase initial signal PWM1n can be obtained by comparing the anti-phase signal VSn against triangular wave signal TRI1. Anti-phase delayed signal PWM2n can be obtained by comparing the anti-phase signal VSn against triangular wave signal TRI2. The duty cycle of anti-phase delayed signal PWM2n can be the same as that of anti-phase initial signal PWM1n, and anti-phase delayed signal PWM2n can be delayed by time Td relative to anti-phase initial signal PWM1n.

Moreover, since in-phase signal VSp and anti-phase signal VSn are opposite in phase, the duty cycle of in-phase initial signal PWM1p and in-phase delayed signal PWM2p can be D, while the duty cycle of anti-phase initial signal PWM1n and anti-phase delayed signal PWM2n can be 1-D, where D<1. In-phase initial signal PWM1p and in-phase delayed signal PWM2p can be performed by a logic AND operation, in order to generate in-phase pulse-width modulation signal PWM3p corresponding to the in-phase signal of the audio signal, having a duty cycle reduced to D-Td. Anti-phase initial signal PWM1n and anti-phase delayed signal PWM2n can be performed by a logic AND operation, in order to generate anti-phase pulse-width modulation signal PWM3n corresponding to the anti-phase signal of the audio signal, having a duty cycle reduced to 1-D-Td. The reduction in duty cycle can reduce the inductor charging time per cycle in the subsequent output filter circuit, thereby reducing ripple current and lowering losses. The reduction in duty cycle may also reduce the common-mode components of the differential signal, further reducing losses. The modulator in this example can also be implemented using program instructions running on a general-purpose data processor (e.g., a DSP).

The embodiments of the present invention can dynamically control a delay parameter according to an envelope of the input signal to perform dynamic duty cycle reduction on the pulse-width modulation signal obtained by preliminary modulation. Thus, the duty cycle of the pulse-width modulation signal obtained by modulating the audio signal can be effectively reduced for small signals, reducing ripple current in the output filter circuit of the Class D amplifier, reducing the charging time and inductor current for the inductor in the output filter circuit, thereby reducing conduction loss and switching loss, and optimizing the power consumption of the Class D amplifier.

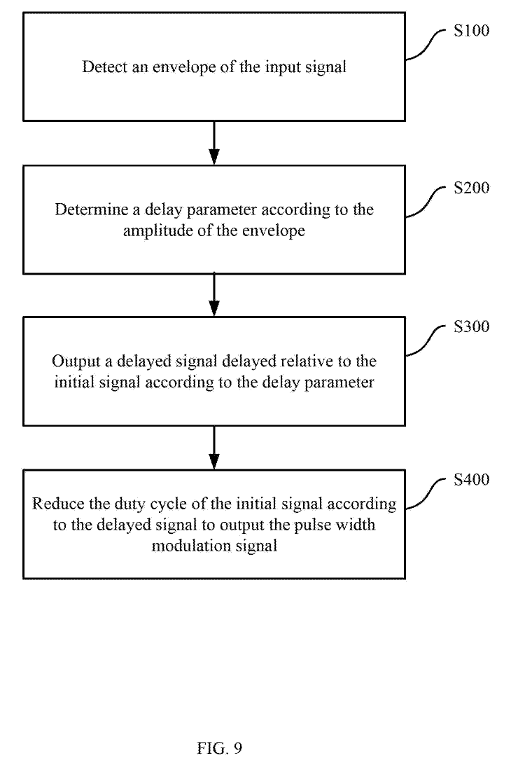

Referring now to FIG. 9, shown is a flow diagram of an example modulation method, in accordance with embodiments of the present invention. In this particular example, the modulation method can be applied in a Class D amplifier or in other types of systems requiring modulation of pulse-width modulation signals. The method in this example can convert an input signal (differential or single-ended) into a pulse-width modulation signal. The method in this example can include the following steps. An envelope of the input signal can be detected, and a duty cycle of an initial signal can be reduced according to an amplitude of the envelope to output a corresponding pulse-width modulation signal. For example, the initial signal can be a signal obtained by performing pulse-width modulation on the input signal.

As shown in FIG. 9, the above steps of the method in this example may include the following. At S100, an envelope of the input signal can be detected. At S200, a delay parameter can be determined according to the amplitude of the envelope. At S300, a delayed signal delayed relative to the initial signal according to the delay parameter can be output. At S400, the duty cycle of the initial signal can be reduced according to the delayed signal to output the pulse-width modulation signal. For example, the initial signal can be a pulse-width modulation signal obtained by performing pulse-width modulation on the input signal.

In one embodiment, S300 can include delaying the initial signal according to the delay parameter to output the delayed signal. In another embodiment, S300 can include delaying a carrier according to the delay parameter, and comparing the input signal against the delayed carrier to output the delayed signal, where the carrier can be used for performing pulse-width modulation on the input signal to determine the initial signal. Further, the carrier may be a triangular wave signal.

In one embodiment, S400 can include performing a logic AND operation on the initial signal and the delayed signal. In one embodiment, to improve interference immunity, the audio signal can be a differential signal, including an in-phase signal and an anti-phase signal. The outputting the delayed signal delayed relative to the initial signal according to the delay parameter can include generating a first triangular wave signal and a second triangular wave signal, where the second triangular wave signal can be delayed relative to the first triangular wave signal by the delay parameter, respectively comparing the in-phase signal against the first triangular wave signal and the second triangular wave signal, in order to respectively generate an in-phase initial signal and an in-phase delayed signal, and respectively comparing the anti-phase signal against the first triangular wave signal and the second triangular wave signal, in order to respectively generate an anti-phase initial signal and an anti-phase delayed signal respectively.

Further, the generating a first triangular wave signal and a second triangular wave signal can include generating a first clock signal and a second clock signal delayed relative to the first clock signal according to the delay parameter, based on a reference clock and the delay parameter, generating the first triangular wave signal according to the first clock signal, and generating the second triangular wave signal according to the second clock signal.

In one embodiment, the determining a delay parameter according to the amplitude of the envelope can include generating a corresponding delay parameter according to a predetermined relationship between the amplitude of the envelope and a delay, the amplitude of the envelope, and at least one time parameter for controlling delay variation. Thus, the delay parameter can be adjusted dynamically in real time according to the amplitude of the envelope. When the amplitude of the envelope can be large, the determined delay parameter can be small, thereby not adjusting the duty cycle by a large margin. When the amplitude of the envelope is small, the determined delay parameter can be large, the duty cycle of the initial signal can be reduced by a large margin, keeping the duty cycle of the pulse-width modulation signal to be amplified relatively small, in the small-signal state, and thereby reducing ripple current and lowering losses.

In one embodiment, the at least one time parameter for controlling delay variation can include a hold time, a release time, and a startup time. When the amplitude of the envelope decreases causing the delay parameter to need to change according to the predetermined relationship between the amplitude of the envelope and a delay, the delay parameter remains unchanged for the hold time and then changes at a speed defined by the release time. When the amplitude of the envelope increases causing the delay parameter to need to change according to the predetermined relationship between the amplitude of the envelope and a delay, the delay parameter changes at a speed defined by the startup time.

In one embodiment, the predetermined relationship between the amplitude of the envelope and a delay can be a piecewise function. Further, when the amplitude of the envelope is less than a first envelope threshold, the delay parameter can be a constant first value. Optionally, in response to the amplitude of the envelope being greater than the first envelope threshold and less than a second envelope threshold, the delay parameter can be a second value that decreases as the amplitude of the envelope increases, and in response to the amplitude of the envelope being greater than the second envelope threshold, the delay parameter can be zero.

Particular embodiments can dynamically control a delay parameter according to an envelope of an input signal to dynamically reduce the duty cycle of a pulse-width modulation signal obtained by preliminary modulation. Thus, the duty cycle of the pulse-width modulation signal obtained by modulating an audio signal can be effectively reduced for small signals, thereby reducing conduction loss and switching loss of the Class D amplifier and optimizing power consumption.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A modulator, configured to convert an input signal into a pulse-width modulation signal, the modulator comprising:
a) an envelope detection unit, configured to receive the input signal, to detect an envelope of the input signal, and to output an amplitude of the envelope of the input signal;
b) wherein the modulator is configured to reduce a duty cycle of an initial signal according to the amplitude of the envelope, in order to output the pulse-width modulation signal; and
c) wherein the initial signal is obtained by performing pulse-width modulation on the input signal.

2. The modulator of claim 1, further comprising:
a) a delay parameter generation unit, configured to generate a delay parameter according to the amplitude of the envelope;
b) a delay unit, configured to output a delayed signal delayed relative to the initial signal according to the delay parameter; and
c) a logic unit, configured to reduce the duty cycle of the initial signal according to the delayed signal, and to output the pulse-width modulation signal.

3. The modulator of claim 2, wherein the delay unit is configured to delay the initial signal according to the delay parameter, in order to output the delayed signal.

4. The modulator of claim 2, wherein:
a) the delay unit is configured to delay a carrier according to the delay parameter, and to perform pulse-width modulation on the input signal according to the delayed carrier to output the delayed signal; and
b) the carrier is used for performing pulse-width modulation on the input signal to determine the initial signal.

5. The modulator of claim 2, wherein the logic unit is a logic AND circuit, configured to perform a logic AND operation on the initial signal and the delayed signal.

6. The modulator of claim 2, wherein the input signal is a differential signal, comprising an in-phase signal and an anti-phase signal.

7. The modulator of claim 6, wherein the delay unit comprises:
a) a comparison unit, configured to respectively compare the in-phase signal against a first triangular wave signal and a second triangular wave signal, in order to respectively generate an in-phase initial signal and an in-phase delayed signal delayed relative to the in-phase initial signal; and
b) being configured to respectively compare the anti-phase signal against the first triangular wave signal and the second triangular wave signal, in order to respectively generate an anti-phase initial signal and an anti-phase delayed signal delayed relative to the anti-phase initial signal.

8. The modulator of claim 7, wherein the delay unit further comprises:
a) a clock generator, configured to generate a first clock signal and a second clock signal delayed relative to the first clock signal according to the delay parameter and a reference clock; and
b) a triangular wave generator, configured to generate the first triangular wave signal according to the first clock signal, and to generate the second triangular wave signal according to the second clock signal.

9. The modulator of claim 7, wherein the comparison unit comprises:
a) a first comparator, configured to receive the in-phase signal of the input signal and the first triangular wave signal, in order to generate the in-phase initial signal;
b) a second comparator, configured to receive the anti-phase signal of the input signal and the first triangular wave signal, in order to generate the anti-phase initial signal;
c) a third comparator, configured to receive the in-phase signal of the input signal and the second triangular wave signal, in order to generate the in-phase delayed signal; and
d) a fourth comparator, configured to receive the anti-phase signal of the input signal and the second triangular wave signal, in order to generate the anti-phase delayed signal.

10. The modulator of claim 1, wherein:
a) the modulator is configured to determine a delay parameter according to the amplitude of the envelope of the input signal, and to reduce the duty cycle of the initial signal according to the delay parameter; and
b) the delay parameter is generated according to a predetermined relationship between the amplitude of the envelope and a delay time, the amplitude of the envelope, and at least one time parameter for controlling variation of the delay time and reduces the duty cycle of the initial signal according to the delay parameter.

11. The modulator of claim 10, wherein:
a) the at least one time parameter for controlling the variation of the delay time comprises a hold time, a release time, and a startup time;
b) when the amplitude of the envelope decreases causing the delay parameter to need to increase according to the predetermined relationship between the amplitude of the envelope and a delay time, the delay parameter remains unchanged for the hold time and then changes at a speed defined by the release time; and
c) when the amplitude of the envelope increases causing the delay parameter to need to decrease according to the predetermined relationship between the amplitude of the envelope and a delay time, the delay parameter changes at a speed defined by the startup time.

12. The modulator of claim 10, wherein the predetermined relationship between the amplitude of the envelope and a delay time is:
a) in response to the amplitude of the envelope being less than a first envelope threshold, the delay parameter is a constant first value;
b) in response to the amplitude of the envelope being greater than the first envelope threshold and less than a second envelope threshold, the delay parameter is a second value that decreases as the amplitude of the envelope increases; and
c) in response to the amplitude of the envelope being greater than the second envelope threshold, the delay parameter is zero.

13. The modulator of claim 1, wherein the input signal is an audio signal, and the modulator is used in a Class D amplifier.

14. A method of modulation for converting an input signal into a pulse-width modulation signal, the method comprising:
a) detecting an envelope of the input signal;
b) reducing a duty cycle of an initial signal according to an amplitude of the envelope, in order to output a corresponding pulse-width modulation signal; and
c) wherein the initial signal is a signal obtained by performing pulse-width modulation on the input signal.

15. The method of claim 14, wherein the detecting the envelope of the input signal, and the reducing the duty cycle of the initial signal according to the amplitude of the envelope to output the corresponding pulse-width modulation signal, comprises:
a) detecting the envelope of the input signal;
b) determining a delay parameter according to the amplitude of the envelope;
c) outputting a delayed signal delayed relative to the initial signal according to the delay parameter; and
d) reducing the duty cycle of the initial signal according to the delayed signal to output the pulse-width modulation signal.

16. The method of claim 15, wherein the outputting the delayed signal delayed relative to the initial signal according to the delay parameter comprises delaying the initial signal according to the delay parameter to output the delayed signal.

17. The method of claim 15, wherein the outputting the delayed signal delayed relative to the initial signal according to the delay parameter comprises:
a) delaying a carrier according to the delay parameter;
b) performing pulse-width modulation on the input signal according to the delayed carrier to output the delayed signal; and
c) wherein the carrier is used for performing pulse-width modulation on the input signal to determine the initial signal.

18. The method of claim 15, wherein the reducing the duty cycle of the initial signal according to the delayed signal comprises performing a logic AND operation on the initial signal and the delayed signal.

19. The method of claim 15, wherein the input signal is a differential signal, comprising an in-phase signal and an anti-phase signal.

20. The method of claim 19, wherein the outputting the delayed signal delayed relative to the initial signal according to the delay parameter comprises:
a) generating a first triangular wave signal and a second triangular wave signal, wherein the second triangular wave signal is delayed relative to the first triangular wave signal by the delay parameter;
b) respectively comparing the in-phase signal against the first triangular wave signal and the second triangular wave signal, in order to respectively generate an in-phase initial signal and an in-phase delayed signal delayed relative to the in-phase initial signal; and
c) respectively comparing the anti-phase signal against the first triangular wave signal and the second triangular wave signal, in order to respectively generate an anti-phase initial signal and an anti-phase delayed signal delayed relative to the anti-phase initial signal.

21. The method of claim 20, wherein the generating the first triangular wave signal and the second triangular wave signal comprises:
a) generating a first clock signal and a second clock signal delayed relative to the first clock signal according to the delay parameter and a reference clock;]
b) generating the first triangular wave signal according to the first clock signal; and
c) generating the second triangular wave signal according to the second clock signal.

22. The method of claim 15, wherein the determining the delay parameter according to the amplitude of the envelope comprises generating the delay parameter according to a predetermined relationship between the amplitude of the envelope and a delay time, the envelope amplitude, and at least one time parameter for controlling delay variation.

23. The method of claim 22, wherein:
a) the at least one time parameter for controlling delay variation comprises a hold time, a release time, and a startup time;
b) when the amplitude of the envelope decreases causing the delay parameter to need to increase according to the predetermined relationship between the amplitude of the envelope and a delay time, the delay parameter remains unchanged for the hold time and then changes at a speed defined by the release time; and
c) when the amplitude of the envelope increases causing the delay parameter to need to decrease according to the predetermined relationship between the amplitude of the envelope and a delay, the delay parameter changes at a speed defined by the startup time.

24. The method of claim 22, wherein the predetermined relationship between the amplitude of the envelope and a delay time is:
a) in response to the amplitude of the envelope being less than a first envelope threshold, the delay parameter is a constant first value;
b) in response to the amplitude of the envelope being greater than the first envelope threshold and less than a second envelope threshold, the delay parameter is a second value that decreases as the amplitude of the envelope increases; and
c) in response to the amplitude of the envelope being greater than the second envelope threshold, the delay parameter is zero.

25. A Class D amplifier, comprising the modulator of claim 1, and being configured to convert an audio signal into the pulse-width modulation signal, the Class D amplifier comprising:
a) a power switching circuit, configured to receive an output signal of the modulator, and to amplify the output signal of the modulator; and
b) an output filter circuit, configured to receive an output signal of the power switching circuit, and to filter the output signal of the power switching circuit, in order to generate a signal for driving a load.
